(19) United States
(12) Patent Application Publication
(10) Pub. No.: US 2026/0239580 A1
(43) Pub. Date: Aug. 13, 2026

(54) COOLING SYSTEM

(71) Applicant: MITSUBISHI HEAVY INDUSTRIES, LTD., Tokyo (JP)

(72) Inventors: Nobuhide HARA, Tokyo (JP); Toshiyuki ISHIDA, Tokyo (JP)

(73) Assignee: MITSUBISHI HEAVY INDUSTRIES, LTD., Tokyo (JP)

(21) Appl. No.: 19/155,810

(22) PCT Filed: Sep. 26, 2023
(86) PCT No.: PCT/JP2023/034905

§ 371 Date: Aug. 12, 2025

(30) Foreign Application Priority Data
Feb. 22, 2023 (JP) 2023-026263

(51) Int. Cl. H05K 7/20

(52) U.S. Cl. CPC H05K 7/20809; H05K 7/20327; H05K 7/20381; H05K 7/20318

(57) ABSTRACT

A cooling system according to the present disclosure comprises: a plurality of racks that each accommodate a heat generator, supply lines that supply respective racks with a coolant for cooling the heat generators; discharge lines that discharge the coolant that has passed through the racks; a turbine into which the coolant that has circulated through each discharge line is introduced and that is rotationally driven by the coolant; a cooling part that cools the coolant that has traveled through the turbine, and leads the cooled coolant to the supply lines; and pumps that are provided to respective supply lines and are capable of being driven independently of each other and that pumps the coolant to the racks.

### TECHNICAL FIELD

The present disclosure relates to a cooling system.

Priority is claimed on Japanese Patent Application No. 2023-026263, filed in Japan on Feb. 22, 2023, the content of which is incorporated herein by reference.

### BACKGROUND ART

PTL 1 discloses a cooling system that efficiently cools an entire electronic device using a liquid refrigerant and that can easily reuse waste heat of the electronic device. An electronic device includes a plurality of heat-generating elements mounted on a substrate. A cooling system includes: a package member that covers the entirety of a substrate including a heat-generating element; a container that stores a liquid refrigerant; a holder that holds the package member in a state of being immersed in the liquid refrigerant in the container; and a refrigerant circulation mechanism that forms a refrigerant flow inside the container. The refrigerant circulation mechanism includes a refrigerant circulation pipe that takes out a liquid refrigerant at a relatively high temperature from an outlet of the container and that returns a liquid refrigerant at a relatively low temperature to an inlet of the container. A generator that generates electric power using the liquid refrigerant taken out from the container is provided in the refrigerant circulation pipe.

### CITATION LIST

### Patent Literature

[PTL 1] Japanese Unexamined Patent Application Publication No. 2013-187251

### SUMMARY OF INVENTION

### Technical Problem

However, in the cooling system described in PTL 1, in a case where a plurality of containers for storing the liquid refrigerant are provided and the high-temperature liquid refrigerant is taken out from each container and used for power generation, the liquid refrigerant may not be sufficiently heated. As a result of such a liquid refrigerant being sent to the generator, there is a problem in that energy efficiency is reduced.

The present disclosure has been made to solve the above-described problems, and an object of the present disclosure is to provide a cooling system in which a plurality of heat generating bodies can be cooled while heat generated by the plurality of heat generating bodies can be efficiently utilized.

### Solution to Problem

In order to solve the above problems, a cooling system according to the present disclosure includes a plurality of racks, each accommodating a heat generating body; a supply line that supplies a refrigerant for cooling the heat generating body to each of the racks; a discharge line that discharges the refrigerant that has passed through each of the racks; a turbine into which the refrigerant that has flowed through each discharge line is introduced and which is rotationally driven by the refrigerant; a cooling part that cools the refrigerant that has passed through the turbine and that leads the refrigerant to the supply line; and a pump that is provided in each supply line, that is independently drivable, and that pumps the refrigerant to the rack.

### Advantageous Effects of Invention

According to the cooling system of the present disclosure, while the plurality of heat generating bodies are cooled, the heat generated by the plurality of heat generating bodies can be efficiently utilized.

### BRIEF DESCRIPTION OF DRAWINGS

FIG. 1 is a configuration diagram of a cooling system according to a first embodiment of the present disclosure.

FIG. 2 is a functional block diagram of a control device according to the first embodiment of the present disclosure.

FIG. 3 is a flowchart showing a procedure of a refrigerant flow rate method according to the first embodiment of the present disclosure.

FIG. 4 is a view showing a heating part according to a modification example of the first embodiment of the present disclosure.

FIG. 5 is a configuration diagram of a cooling system according to a second embodiment of the present disclosure.

FIG. 6 is a functional block diagram of a control device according to the second embodiment of the present disclosure.

FIG. 7 is a flowchart showing a procedure of a refrigerant flow rate method according to the second embodiment of the present disclosure.

FIG. 8 is a configuration diagram of a cooling system according to a third embodiment of the present disclosure.

FIG. 9 is a configuration diagram of a cooling system according to a fourth embodiment of the present disclosure.

FIG. 10 is a configuration diagram of a cooling system according to a fifth embodiment of the present disclosure.

FIG. 11 is a hardware configuration diagram according to each embodiment of the present disclosure.

FIG. 12 is a schematic diagram of a rack according to a modification example of the present disclosure.

### DESCRIPTION OF EMBODIMENTS

### First Embodiment

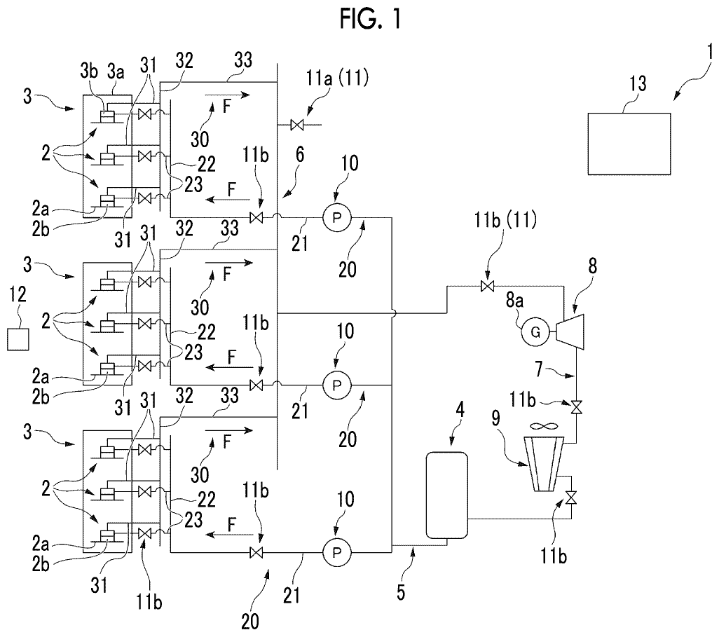

Hereinafter, a cooling system 1 according to a first embodiment of the present disclosure will be described with reference to FIGS. 1 to 3.

The cooling system 1 of the present embodiment shown in FIG. 1 is introduced into, for example, a data center. The cooling system 1 is provided to cool a plurality of servers 2 in the data center. FIG. 1 is a schematic diagram showing an overall configuration of the cooling system 1.

Each server 2 includes a server board 2a and a chip (heat generating body) 2b such as a CPU or a GPU. The chip 2b is mounted on the server board 2a. Since the chip 2b generates heat during operation, the cooling system 1 for cooling the chip 2b is introduced.

### Configuration of Cooling System

As shown in FIG. 1, the cooling system 1 includes a rack 3, a receiver tank 4, a distribution header 5, a supply line 20, a discharge line 30, a collecting header 6, an intermediate line 7, a turbine 8, a generator 8a, a cooling part 9, a pump 10, a valve 11, a sensor 12, and a control unit 13. The cooling system 1 circulates a refrigerant F for cooling the chip 2b. The refrigerant F is, for example, a hydrofluorocarbon (HFC) or hydrofluoroolefin (HFO) type refrigerant F, or water or the like. The type of the refrigerant F is not limited to the above example and can be changed as appropriate.

Hereinafter, a circulation direction of the refrigerant F circulating in the cooling system 1 will be simply referred to as a circulation direction. In addition, an upstream side in the circulation direction of the refrigerant F may be simply referred to as an upstream side, and a downstream side in the circulation direction of the refrigerant F may be simply referred to as a downstream side.

### Rack

A plurality of racks 3 are provided. Each of the plurality of racks 3 accommodates the chip 2b. In the present embodiment, a plurality of servers 2 are accommodated in each rack 3. That is, a plurality of the chips 2b are accommodated in each of the racks 3.

The rack 3 of the present embodiment includes a rack body 3a and a cold plate 3b.

The rack body 3a has an accommodation space in which a plurality of servers 2 are accommodated. The cold plate 3b is provided for each of the chips 2b mounted in the respective servers 2. The refrigerant F is supplied from the receiver tank 4 to the cold plate 3b via the supply line 20.

### Receiver Tank

The receiver tank 4 stores the refrigerant F before being supplied to the rack 3. The liquid-phase refrigerant F is stored in the receiver tank 4. The receiver tank 4 is provided with a distribution header 5.

### Distribution Header

The distribution header 5 distributes the refrigerant F stored in the receiver tank 4 to each rack 3. The distribution header 5 branches as many times as the number of the racks 3 on the downstream side, and one supply line 20 is provided for each branch.

### Supply Line

The supply line 20 supplies the refrigerant F for cooling the chips 2b from the distribution header 5 to each rack 3. A plurality of the supply lines 20 are provided for each of the racks 3. The supply line 20 of the present embodiment supplies the refrigerant F to each cold plate 3b. The supply line 20 is mainly a steam line through which the liquid-phase refrigerant F flows.

The supply line 20 has a first supply line 21, a supply header 22, and a second supply line 23.

The first supply line 21 is connected to a branch on the downstream side of the distribution header 5.

The supply header 22 is provided at a downstream-side end of the first supply line 21. The supply header 22 distributes the refrigerant F flowing through the first supply line 21 to the cold plates 3b. The supply header 22 branches as many times as the number of the cold plates 3b of the corresponding rack 3, and one second supply line 23 is provided for each branch.

The second supply line 23 guides the refrigerant F distributed by the supply header 22 to each cold plate 3b.

The refrigerant F supplied to each rack 3 exchanges heat with the chip 2b. In the present embodiment, the refrigerant F exchanges heat with each chip 2b via each cold plate 3b. In this manner, the refrigerant F evaporates and becomes the gas-phase refrigerant F.

### Discharge Line

The discharge line 30 discharges the refrigerant F that has passed through each rack 3. A plurality of the discharge lines 30 are provided for each rack 3. The discharge line 30 of the present embodiment discharges the refrigerant F from each cold plate 3b. The discharge line 30 is mainly a steam line through which the gas-phase refrigerant F flows.

The discharge line 30 has a first discharge line 31, a discharge header 32, and a second discharge line 33.

A plurality of the first discharge lines 31 are provided for each cold plate 3b. The first discharge line 31 discharges the refrigerant F from each cold plate 3b.

The discharge header 32 is connected to each cold plate 3b by each first discharge line 31. The discharge header 32 merges the refrigerant F from each cold plate 3b.

One second discharge line 33 is provided in the discharge header 32. The refrigerant F merged by the discharge header 32 flows through the second discharge line 33. The second discharge line 33 guides the refrigerant F merged by the discharge header 32 toward the turbine 8.

The second discharge line 33 of each discharge line 30 is connected to the collecting header 6 on the downstream side.

### Collecting Header

The collecting header 6 merges the refrigerant F that has flowed through each rack 3. The collecting header 6 collects the refrigerant F that has flowed through the second discharge line 33 of each discharge line 30 into one flow. A downstream end of the collecting header 6 is connected to the intermediate line 7.

### Intermediate Line

The intermediate line 7 connects the collecting header 6 and the receiver tank 4. The intermediate line 7 guides the refrigerant F that has flowed through the collecting header 6 to the receiver tank 4. The intermediate line 7 is provided with the turbine 8 and the cooling part 9.

### Turbine

The refrigerant F flowing through each discharge line 30 is introduced into the turbine 8. The turbine 8 is rotationally driven by the expansion pressure of the refrigerant F supplied from the discharge line 30. The generator 8a is connected to the turbine 8 of the present embodiment. The generator 8a can be driven and generate power by means of the rotation drive of the turbine 8.

The refrigerant F used in the turbine 8 is guided to the cooling part 9 on the downstream side via the intermediate line 7.

### Cooling Part

The cooling part 9 cools and condenses the gas-phase refrigerant F. Accordingly, the gas-phase refrigerant F becomes the liquid-phase refrigerant F. The cooling method of the cooling part 9 may be air cooling or water cooling. The cooling part 9 is, for example, an air-cooled chiller, a fan, or the like. The refrigerant F cooled by the cooling part 9 is guided to the receiver tank 4 via the intermediate line 7. In the receiver tank 4, the liquid-phase refrigerant F is temporarily stored. The refrigerant F stored in the receiver tank 4 is supplied to each cold plate 3b in each rack 3 again via the supply line 20.

In this way, the refrigerant F circulates inside the cooling system 1. In order to stabilize the flow of the refrigerant F, the cooling system 1 is provided with the pump 10, the sensor 12, the control unit 13, and the like.

### Pump

The pump 10 is provided in each supply line 20. In the present embodiment, the pump 10 is provided one by one in the first supply line 21 of the supply line 20. The plurality of pumps 10 are independently drivable and pump the refrigerant F toward the rack 3.

### Valve

A plurality of the valves 11 are provided in a line configuring the cooling system 1. The illustrated example is merely an example. The number of the valves 11 can be changed as appropriate. The valve 11 of the present embodiment is an electromagnetic valve, and is controlled by the control unit 13 to be described later. The plurality of valves 11 include a gas release valve 11a and a partition valve 11b.

### Gas Release Valve

The gas release valve 11a is provided on the downstream side of the discharge line 30. In the present embodiment, the gas release valve 11a is provided in the collecting header 6. The gas release valve 11a discharges a portion of the gas flowing through the discharge line 30 to adjust the pressure in the discharge line 30. In addition, for example, by performing vacuum drawing or the like via the gas release valve 11a, the non-condensable gas present in the cooling system 1 can be discharged to the outside before the drive.

### Partition Valve

The partition valve 11b adjusts the flow rate of the refrigerant F by adjusting the opening degree of various lines constituting the cooling system 1. In addition, the partition valve 11b can open or close any line of the various lines constituting the cooling system 1. In the present embodiment, the partition valve 11b is provided in the supply line 20 and the intermediate line 7. More specifically, one partition valve 11b is provided on the downstream side of the pump 10 of each first supply line 21, and one partition valve 11b is provided in each second supply line 23. Further, one partition valve 11b is provided on the upstream side of the turbine 8 of the intermediate line 7, one partition valve 11b is provided between the turbine 8 and the cooling part 9 of the intermediate line 7, and one partition valve 11b is provided on the downstream side of the cooling part 9.

### Sensor

The sensor 12 acquires the amount of heat generated for each rack 3. The information on the amount of heat generated for each rack 3 acquired by the sensor 12 is sent to the control unit 13. In a case where the cooling system 1 is introduced into a server center as in the present embodiment, for example, an intelligent power distribution unit (PDU) is adopted as the sensor 12. The intelligent PDU acquires the total amount of heat generated for each rack 3 by monitoring the current value of each rack 3.

### Control Unit

The control unit 13 controls the pumping flow rate of each pump 10 according to the total amount of heat generated for each server 2 acquired by the sensor 12.

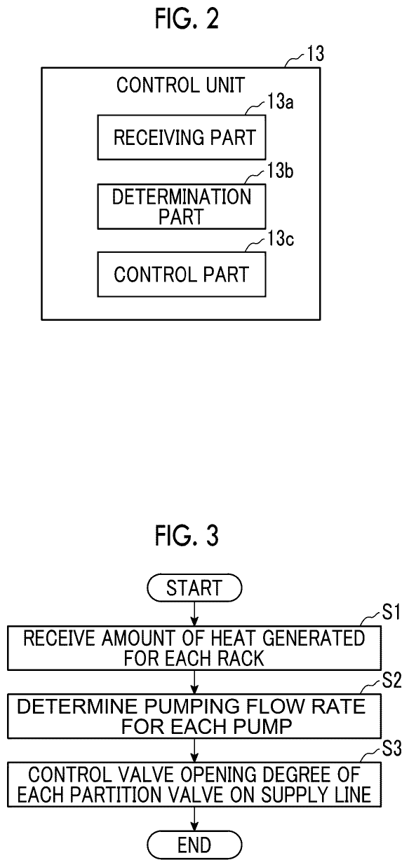

As shown in FIG. 2, the control unit 13 of the present embodiment includes a receiving part 13a, a determination part 13b, and a control part 13c.

The receiving part 13a receives information on the amount of heat generated for each server 2, which is transmitted from the sensor 12.

The determination part 13b determines the pumping flow rate of each pump 10 based on the amount of heat generated for each server 2.

The control part 13c controls the pumping flow rate of each pump 10 based on the determination result of the determination part 13b.

### Procedure of Flow Rate Adjustment Method

Subsequently, a procedure of a method for adjusting the flow rate of the refrigerant F supplied to each server 2 will be described with reference to the flow of FIG. 3.

As shown in FIG. 3, in the flow rate adjustment method according to the first embodiment of the present disclosure, first, the receiving part 13a receives information on the amount of heat generated for each rack 3 acquired by each sensor 12 (step S1). After step S1, the determination part 13b determines the pumping flow rate of each pump 10 based on the amount of heat generated for each rack 3 (step S2). After step S2, the control part 13c controls the pumping flow rate of each pump 10 based on the determination result of the determination part 13b (step S3). In this manner, the refrigerant F having a flow rate suitable for the amount of heat generated is supplied to each server 2. In the present embodiment, in step S3, the control part 13c controls a valve opening degree of each partition valve 11b on the supply line 20. In this manner, the supply amount of the refrigerant F can be controlled for each cold plate 3b. By going through the above steps S1 to S3, the flow rate of the refrigerant F to each server 2 is adjusted.

In addition, in the procedure of the flow rate adjustment method of the refrigerant F, superheating degree control may be used, for example, as in an air conditioner. In the superheating degree control, the control unit 13 adjusts the valve opening degree of the partition valve 11b on the supply line 20 with the refrigerant gas superheating degree (superheating degree of the gas-phase refrigerant F) calculated from the pressure and the temperature at an outlet of the cold plate 3b.

### Operations and Effects

Subsequently, the operations and effects of the cooling system 1 described above will be described.

In the present embodiment, the cooling system 1 includes the plurality of racks 3, the supply line 20, the discharge line 30, the turbine 8, the cooling part 9, and the pump 10. Each of the plurality of racks 3 accommodates the chip 2b. The supply line 20 supplies the refrigerant F for cooling the chips 2b to each rack 3. The discharge line 30 discharges the refrigerant F that has passed through each rack 3. The turbine 8 is introduced with the refrigerant F flowing through each discharge line 30, and is rotationally driven by the refrigerant F. The cooling part 9 cools the refrigerant F that has passed through the turbine 8 and leads the refrigerant F to the supply line 20. The pump 10 is provided in each supply line 20, can be driven independently, and pumps the refrigerant F to the rack 3.

According to the present embodiment, the pumps 10 provided for each supply line 20 can be driven independently of each other. Therefore, the pump 10 can be controlled for each supply line 20. In this manner, the supply amount of the refrigerant F to each chip 2b can be controlled according to the amount of heat generated. Therefore, the plurality of chips 2b can be efficiently cooled. In addition, the refrigerant F in an amount corresponding to the amount of heat generated for each chip 2b is supplied to each chip 2b in this way, and the refrigerant F can be efficiently heated. For this reason, the refrigerant F can be sufficiently heated to a vicinity of a vaporization temperature and can be brought into a heated state in a vicinity of an outlet of the rack 3 in the circulation cycle of the refrigerant F in the cooling system 1. In this way, the turbine 8 can be stably rotationally driven by the refrigerant F sufficiently heated by each chip 2b. Therefore, according to the present embodiment, the heat generated by the plurality of chips 2b can be efficiently utilized.

In particular, in the present embodiment, the refrigerant F is boiled in the rack 3 to form the gas-phase refrigerant F, and the heat generated by the chip 2b is largely recovered by the refrigerant F. Further, thereafter, the gas-phase refrigerant F is collected from each rack 3 and guided to the turbine 8. In general, the amount of heat generated by each chip 2b is small and it is difficult to use the heat. However, as in the present embodiment, the heat generated by each chip 2b can be efficiently used by collecting the refrigerant F after boiling the refrigerant F and guiding the refrigerant F to the turbine 8.

In addition, a generator 8a is connected to the turbine 8 of the present embodiment, and power generation can be performed by rotationally driving the turbine 8. That is, in the present embodiment, the cooling system 1 can efficiently cool the heat generated by the plurality of chips 2b and can generate power by using the heat generated by the plurality of chips 2b. Furthermore, the power required for cooling the chip 2b can also be covered by the electric power generated in this way. Therefore, the annual electricity cost can be reduced, and even if the initial investment increases due to the introduction of the cooling system 1 of the present embodiment, the cost can be sufficiently reduced.

In addition, since the pressure of the cooling part 9 can be set to be lower as the outside air temperature becomes lower, the differential pressure across the turbine 8 becomes larger, and the turbine 8 can be efficiently driven.

In the present embodiment, the rack 3 has the cold plate 3b provided for each of the chips 2b. The supply line 20 supplies the refrigerant F to each cold plate 3b. The discharge line 30 discharges the refrigerant F from each cold plate 3b.

Accordingly, since each of the chips 2b can be locally cooled, the plurality of chips 2b can be more efficiently cooled. In addition, the heat generated in each chip 2b can be efficiently recovered by the refrigerant F and can be used for rotational drive of the turbine 8. Therefore, energy efficiency can be further improved.

In addition, in the immersion method of cooling the server 2 by immersing the server 2 in the refrigerant F, it is difficult to ensure a seal so that the refrigerant F does not leak at a connection location with the supply line 20 or the discharge line 30. However, by adopting the cold plate 3b as in the present embodiment, it becomes easy to ensure a seal at the connection location with the supply line 20 or the discharge line 30.

In the present embodiment, one partition valve 11b is installed in each second supply line 23. That is, the partition valve 11b is provided for each cold plate 3b.

In this manner, the supply of the refrigerant F can be cut off for each cold plate 3b. Therefore, since each server 2 can be easily separated and isolated, individual maintenance of the server 2 is facilitated. The partition valves 11b that cut off the supply of the refrigerant F to each cold plate 3b may automatically cut off the second supply line 23 by removing the cold plate 3b, for example, similar to a check valve.

In the present embodiment, the sensor 12 and the control unit 13 are provided. The sensor 12 detects the amount of heat generated for each rack 3. The control unit 13 controls the pumping flow rate of the pump 10 according to the amount of heat generated for each rack 3.

In this manner, the refrigerant F corresponding to the amount of heat generated by each chip 2b can be accurately supplied to each chip 2b. Therefore, the heat generated in each chip 2b can be more efficiently recovered by the refrigerant F. In this way, the supply amount of the refrigerant F can be automatically controlled according to the amount of heat generated for each chip 2b, and the heat generated by each chip 2b can be utilized more efficiently.

### Modification Example of First Embodiment

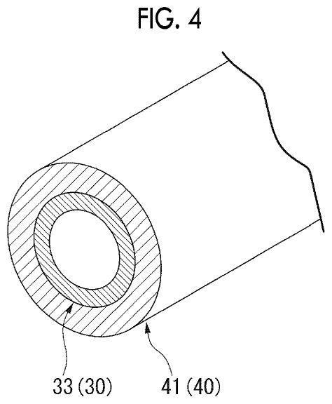

Subsequently, a modification example of the first embodiment described above will be described with reference to FIG. 4.

As shown in FIG. 4, the cooling system 1 further includes a heating part 40 provided in the discharge line 30.

### Heating Part

The heating part 40 heats the refrigerant F flowing through the discharge line 30. The heating part 40 of the present modification example is a cylindrical heat storage material 41 that covers the outside of the discharge line 30. In the illustrated example, the heat storage material 41 is provided on an outer peripheral surface of the second discharge line 33 of the discharge line 30. The heat storage material 41 stores the heat of sunlight and transmits the heat of sunlight to the refrigerant F in the discharge line 30.

In this way, in the present modification example, the cooling system 1 includes the heating part 40 provided in the supply line 20.

In this manner, the temperature of the refrigerant F after passing through the rack 3 can be adjusted to a temperature sufficient to drive the turbine 8 by heating the refrigerant F with the heating part 40. Therefore, the refrigerant F that is insufficiently heated can be preheated before being introduced into the turbine 8. Therefore, the turbine 8 can be operated more efficiently.

In the present modification example, a case where the heating part 40 stores the heat of the sunlight and transmits the heat of the sunlight to the refrigerant F to heat the refrigerant F has been described. However, the present invention is not limited thereto. The heating part 40 may be a solar heater or a heater that uses another heat source.

### Second Embodiment

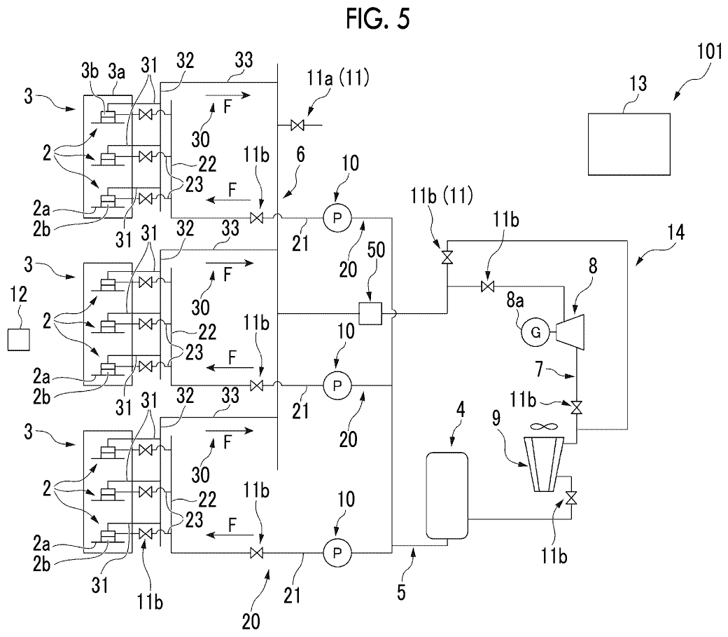

Hereinafter, a cooling system 101 according to a second embodiment of the present disclosure will be described with reference to FIGS. 5 to 7. Among the configurations of the second embodiment, the same configurations as those of the above-described embodiment will be given the same names, reference signs, and the like, and the description thereof will be omitted as appropriate.

As shown in FIG. 5, in the present embodiment, the cooling system 101 further includes a branch line 14 and a second sensor 50.

### Branch Line

The branch line 14 branches the refrigerant F that has flowed through the discharge line 30 to the upstream side of the turbine 8, and guides a portion of the branched refrigerant F to the downstream side of the turbine 8. In the present embodiment, one branch line 14 is provided, and the branch line 14 connects the downstream side of the collecting header 6 and a vicinity of an inlet of the cooling part 9 of the intermediate line 7. The branch line 14 branches a portion of the refrigerant F before the refrigerant F is introduced into the turbine 8, and introduces the refrigerant F into the cooling part 9 on the downstream side. The partition valve 11b is provided at an end portion of the branch line 14 on the upstream side. In addition, the end portion of the branch line 14 on the downstream side is located between the partition valve 11b and the cooling part 9 of the intermediate line 7.

### Second Sensor

The second sensor 50 is a pressure sensor that measures a pressure on the upstream side of the turbine 8. The second sensor 50 can measure the pressure in a vicinity of an inlet of the turbine 8. In the present embodiment, the second sensor 50 is provided on the downstream side of the collecting header 6. The control unit 13 controls the valve opening degree of the partition valve 11b of the intermediate line 7 and the branch line 14 based on the measurement result of the second sensor 50.

### Control Unit

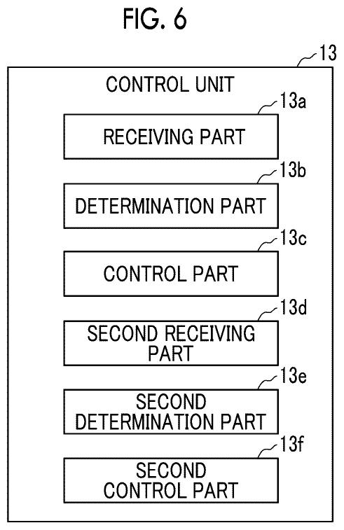

Subsequently, each functional portion of the control unit 13 of the present embodiment will be described with reference to FIG. 6.

As shown in FIG. 6, the control unit 13 further includes a second receiving part 13d, a second determination part 13e, and a second control part 13f.

The second receiving part 13d receives information about the pressure in the vicinity of the inlet of the turbine 8 transmitted from the second sensor 50.

The second determination part 13e determines whether or not the pressure in the vicinity of the inlet of the turbine 8 is a pressure at which the turbine 8 can be driven, based on the received pressure information. In addition, the second determination part determines whether or not the pressure in the vicinity of the inlet of the turbine 8 reaches the pressure upper limit of the turbine 8, based on the received pressure information.

The second control part 13f controls the valve opening degree of the partition valve 11b of the intermediate line 7 and the branch line 14 based on the determination result of the second determination part 13e.

### Control of Partition Valve

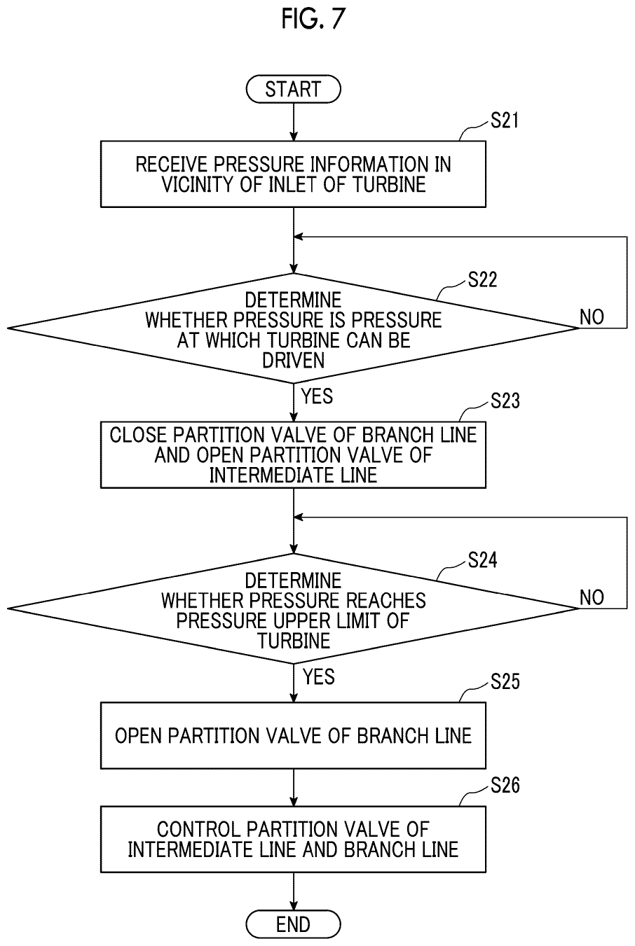

Subsequently, an example of a control procedure of the partition valve 11b of the intermediate line 7 and the branch line 14 will be described with reference to the flow of FIG. 7.

For example, at a time when the amount of heat generated immediately after the cooling system 101 is driven is small, the pressure inside the cooling system 101 does not rise to an extent that the turbine 8 can be driven. Therefore, it is preferable that the refrigerant F is circulated without passing through the turbine 8 until the pressure inside the cooling system 101 is sufficiently increased. Therefore, hereinafter, as an example, a control procedure for the partition valve 11b of the intermediate line 7 and the branch line 14 will be described in a state where the partition valve 11b on the most upstream side of the intermediate line 7 is closed and the partition valve 11b of the branch line 14 is opened before the cooling system 101 is driven. Here, the opening and closing of the partition valve 11b of the intermediate line 7 will be described. However, unless otherwise specified, the opening and closing of the partition valve 11b on the most upstream side on the intermediate line 7 will be described.

As shown in FIG. 7, first, the second receiving part 13d receives the pressure information in the vicinity of the inlet of the turbine 8 acquired by the second sensor 50 (Step S21). After step S21, the second determination part 13e determines whether or not the pressure in the vicinity of the inlet of the turbine 8 is a pressure at which the turbine 8 can be driven (step S22).

In a case where the pressure in the vicinity of the inlet of the turbine 8 is not a pressure at which the turbine 8 can be driven (step S22; NO), the partition valve 11b of the intermediate line 7 is closed, and the refrigerant F is circulated inside the cooling system 101 with the partition valve 11b of the branch line 14 being open.

In a case where the pressure in the vicinity of the inlet of the turbine 8 is a pressure at which the turbine 8 can be driven (step S22; YES), the second control part 13f closes the partition valve 11b of the branch line 14 and opens the partition valve 11b of the intermediate line 7 (step S23). At this time, the partition valve 11b of the branch line 14 may be gradually closed and the partition valve 11b of the intermediate line 7 may be gradually opened while monitoring the pressure in the vicinity of the inlet of the turbine 8. After step S23, the second determination part 13e determines whether or not the pressure in the vicinity of the inlet of the turbine 8 is the pressure upper limit of the turbine 8 (step S24).

When the pressure in the vicinity of the inlet of the turbine 8 is not the pressure upper limit of the turbine 8 (step S24; NO), the partition valve 11b of the intermediate line 7 is opened, and the refrigerant F is circulated in the cooling system 101 with the partition valve 11b of the branch line 14 closed. In a case where the cooling of the chip 2b is not required, the drive of the cooling system may be stopped at this point.

In a case where the pressure in the vicinity of the inlet of the turbine 8 is the pressure upper limit of the turbine 8 (step S24; YES), the second control part 13f again opens the partition valve 11b of the branch line 14 (step S25). In this state, the refrigerant F is circulated. After step S25, the second control part 13f controls the valve opening degree of the partition valve 11b of the intermediate line 7 and the partition valve 11b of the branch line 14 according to the pressure in the vicinity of the inlet of the turbine 8. When the cooling of the chip 2b is not required, the drive of the cooling system 101 is stopped.

The partition valve 11b of the intermediate line 7 and the branch line 14 is controlled by the above-described procedure.

### Operations and Effects

Subsequently, the operations and effects of the cooling system 101 described above will be described.

In the present embodiment, the cooling system 101 further includes the branch line 14 that branches the refrigerant F that has flowed through the discharge line 30 on the upstream side of the turbine 8 and that guides a portion of the branched refrigerant F to the downstream side of the turbine 8.

In this manner, a portion of the refrigerant F can be released from the branch line 14, and the internal pressure in the turbine 8 can be reduced. In this manner, a load applied to the turbine 8 can be reduced. For this reason, an amount of steam flowing through the turbine 8 can be stabilized.

For example, in a case where the total amount of heat generated for each rack 3 increases due to the addition of the server 2 or the like and the load on the turbine 8 exceeds the upper limit, a portion of the refrigerant F can be diverted and released through the branch line 14 by opening the partition valve 11b provided in the branch line 14. Accordingly, since the load on the turbine 8 can be reduced, the output of the turbine 8 can be kept constant, and a power generation amount can be kept constant.

### Third Embodiment

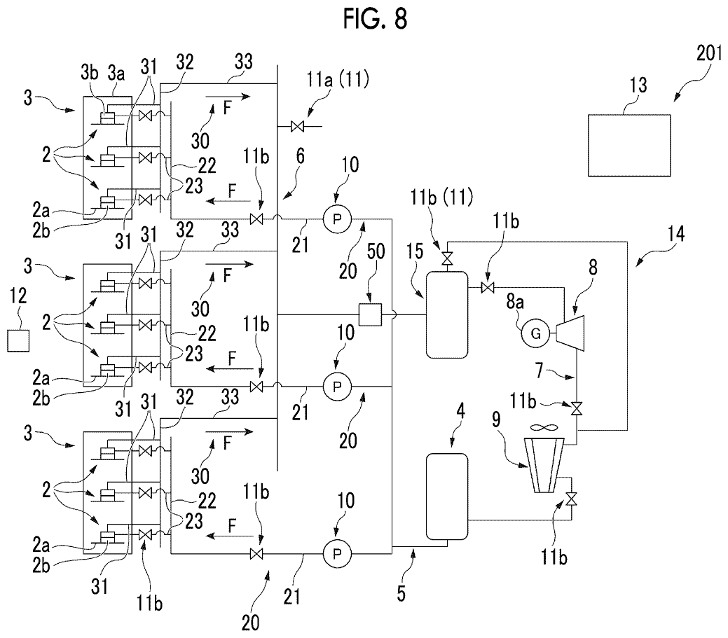

Hereinafter, a cooling system 201 according to a third embodiment of the present disclosure will be described with reference to FIG. 8. Among the configurations of the third embodiment, the configurations common to the above-described embodiments will be omitted as appropriate from the description by giving the same names, reference signs, or the like.

As shown in FIG. 8, in the present embodiment, the cooling system 201 further includes a buffer tank 15.

### Buffer Tank

The buffer tank 15 is disposed on the upstream side of the turbine 8 and is capable of storing the refrigerant F that has flowed through the discharge line 30. In the present embodiment, the buffer tank 15 is provided at a connection location between the collecting header 6 and the intermediate line 7. Further, an upstream end of the branch line 14 is connected to the buffer tank 15.

### Operations and Effects

Subsequently, the operations and effects of the cooling system 201 described above will be described.

When the load of the calculation of the chip 2b fluctuates, the amount of heat generated also fluctuates, and the heating degree of the refrigerant F fluctuates. Accordingly, the vapor pressure of the refrigerant F fluctuates, and thus the pressure of the refrigerant F in the cooling system 201 also fluctuates, and the pressure in the cooling system 201 becomes unstable.

As a countermeasure, in the present embodiment, the cooling system 201 is further provided with the buffer tank 15 that is disposed on the upstream side of the turbine 8 and that is capable of storing the refrigerant F that has flowed through the discharge line 30.

In this manner, the refrigerant F recovered from each rack 3 can be stored in the buffer tank 15 once, and the pressure can be made uniform and stabilized in the buffer tank 15. Thereafter, the refrigerant F can be supplied to the turbine 8, so that the amount of steam flowing through the turbine 8 can be further stabilized.

### Fourth Embodiment

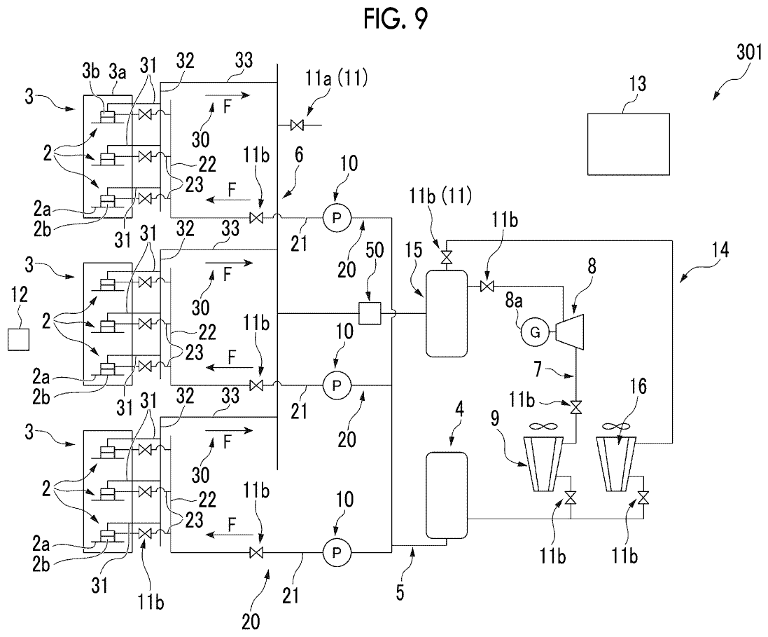

Hereinafter, a cooling system 301 according to a fourth embodiment of the present disclosure will be described with reference to FIG. 9. Among the configurations of the second embodiment, the same configurations as those of the above-described embodiments will be given the same names, reference signs, and the like, and the description thereof will be omitted as appropriate.

As shown in FIG. 9, in the present embodiment, the branch line 14 bypasses the turbine 8 and the cooling part 9 and is connected to the receiver tank 4. In addition, the cooling system 301 includes a second cooling part 16.

### Second Cooling Part

The second cooling part 16 is provided in the branch line 14. The second cooling part 16 cools the refrigerant F and leads the refrigerant F to the supply line 20. The second cooling part 16 is a condenser similar to the cooling part 9. That is, the cooling method of the second cooling part 16 may be air cooling or water cooling. The second cooling part 16 is, for example, an air-cooled chiller or a fan, as with the cooling part 9. The refrigerant F cooled by the second cooling part 16 is guided to the receiver tank 4 via the branch line 14.

In addition, in the present embodiment, the partition valves 11b are provided on the upstream side and the downstream side of the second cooling part 16 in the branch line 14.

### Operations and Effects

Subsequently, the operations and effects of the cooling system 301 described above will be described.

In the present embodiment, the cooling system 301 further includes the second cooling part 16 that is provided in the branch line 14, that cools the refrigerant F, and that leads the refrigerant F to the supply line 20.

In this manner, the refrigerant F flowing through the branch line 14 can be cooled and condensed by the second cooling part 16. Therefore, since the pressure of the branch line 14 can be lowered, a decrease in the front-rear differential pressure of the turbine 8 can be suppressed, and the output of the turbine 8 can be kept constant. In this manner, the operation of the cooling system 301 is stabilized. Therefore, the operable pressure range of the cooling system 301 can be expanded.

### Fifth Embodiment

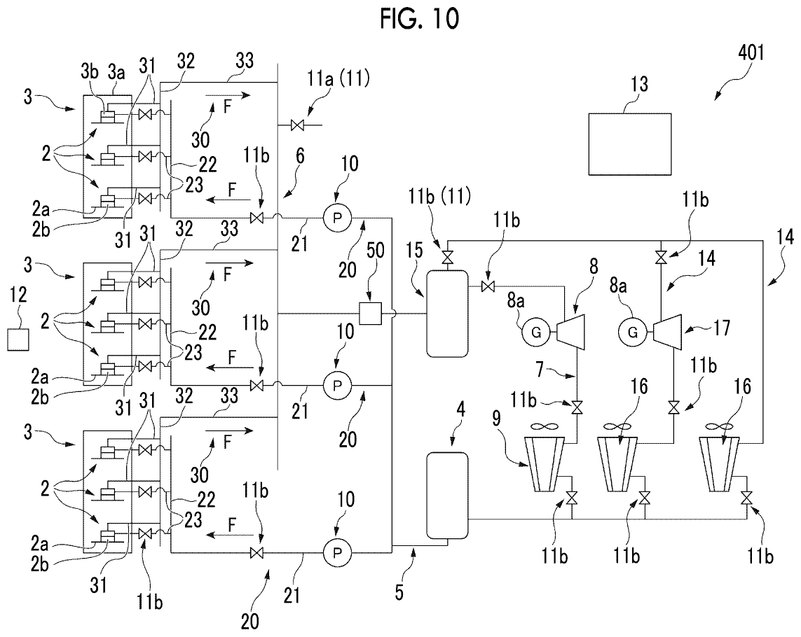

Hereinafter, a cooling system 401 according to a fifth embodiment of the present disclosure will be described with reference to FIG. 10. Among the configurations of the fifth embodiment, the configurations common to the above-described embodiments will be omitted as appropriate from the description by giving the same names, reference signs, or the like.

As shown in FIG. 10, in the present embodiment, a plurality of branch lines 14 are provided. In the illustrated example, two branch lines 14 are provided. The second cooling part 16 is provided one by one in each branch line 14. In addition, the cooling system 401 includes a second turbine 17.

### Second Turbine

For example, the second turbine 17 is provided in one branch line 14 of the two branch lines 14. The second turbine 17 is provided on the upstream side of the second cooling part 16 in the branch line 14. The second turbine 17 is rotationally driven by the expansion pressure of the refrigerant F. The generator 8a is connected to the second turbine 17 of the present embodiment, as in the case of the turbine 8. The generator 8a can be driven and generate power by being rotationally driven by the second turbine 17.

In the illustrated example, in the branch line 14 in which the second turbine 17 is provided, one partition valve 11b is further provided on the upstream side and the downstream side of the second turbine 17. The illustrated example is merely an example, and the partition valves 11b may not be provided on the upstream side and the downstream side of the second turbine 17.

In addition, as the outside air temperature becomes lower, the pressure of the second cooling part 16 can be set to be lower similarly to the cooling part 9. Therefore, the differential pressure across the second turbine 17 becomes larger similarly to the turbine 8, and the second turbine 17 can be efficiently driven.

### Operations and Effects

Subsequently, the operations and effects of the cooling system 401 described above will be described.

In the present embodiment, a plurality of branch lines 14 are provided.

In this manner, the flow rate of the refrigerant F that can be released from the branch line 14 can be increased, and the pressure range that can be adjusted by the branch line 14 can be widened.

In the present embodiment, the cooling system 401 is further provided with the second turbine 17 that is provided on the downstream side of the buffer tank 15 of the branch line 14 and on the upstream side of the second cooling part 16 and that is rotationally driven by the refrigerant F.

In this manner, the second turbine 17 can be driven by the refrigerant F released by the branch line 14. Therefore, the heat of the chips 2b recovered by the refrigerant F can be utilized more efficiently. Further, for example, when the turbine 8 is not operated, the second turbine 17 can be operated, and redundancy can be provided. In addition, in a case where a plurality of the branch lines 14 are provided, a plurality of the second turbines 17 can be installed, and the redundancy can be further increased.

### Hardware Configuration

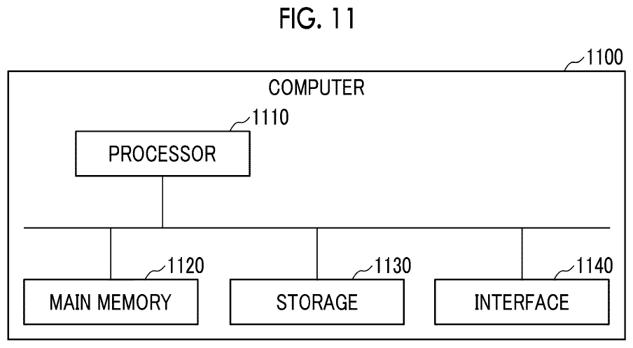

The control unit 13 of each of the above-described embodiments is implemented in a computer 1100 shown in FIG. 11. FIG. 11 is a schematic block diagram showing a configuration of the computer 1100 according to the embodiment. The computer 1100 includes a processor 1110, a main memory 1120, a storage 1130, and an interface 1140.

The operations of the respective functional parts of the control unit 13 described above are stored in the storage 1130 in the form of a program. The processor 1110 reads the program from the storage 1130, deploys the read program in the main memory 1120, and executes the above-described processing in accordance with the program. In addition, the processor 1110 secures a storage area in the main memory 1120 according to the program.

The program may be a program for realizing some functions performed by the computer 1100. For example, the program may cause the computer 1100 to perform the functions in combination with another program stored in the storage 1130 in advance or in combination with another program installed in another device. In addition, the computer 1100 may include a custom large-scale integrated circuit (LSI) such as a programmable logic device (PLD) in addition to or in place of the above configuration. Examples of the PLD include a programmable array logic (PAL), a generic array logic (GAL), a complex programmable logic device (CPLD), and a field-programmable gate array (FPGA). In this case, functions that are realized by the processor 1110 may be partially or entirely realized by an integrated circuit.

As an example of the storage 1130, a magnetic disk, a magneto-optical disk, or a semiconductor memory can be used. The storage 1130 may be an internal medium directly connected to a bus of the computer 1100, or may be an external medium connected to the computer 1100 via the interface 1140 or a communication line. In addition, when this program is distributed to the computer 1100 via the communication line, the computer 1100 receiving the distributed program may deploy the program in the main memory 1120 to execute the above-described processing. The storage 1130 may be a non-temporary tangible storage medium.

In addition, the program may be a program for realizing some of the above-described functions. In addition, the program may be a so-called difference file (difference program) that realizes the above-described functions in combination with another program previously stored in the storage 1130.

### Other Embodiments

The embodiments of the present disclosure have been described in detail hereinabove with reference to the drawings, but specific configurations are not limited to the embodiments, and design changes and the like within a scope that does not deviate from the gist of the present disclosure are also included.

In the above-described embodiments, a case where the cooling systems 1, 101, 201, 301, and 401 are used to cool the chips 2b such as CPUs and GPUs mounted in the server 2 has been described. However, the present disclosure is not limited thereto. The cooling systems 1, 101, 201, 301, and 401 may be used to cool a heat generating body other than the chip 2b.

In the above-described embodiments, a plurality of chips 2b are accommodated in each rack 3. However, the present disclosure is not limited thereto. For example, one chip 2b may be accommodated in each rack 3.

In the above-described embodiments, the pumping flow rate of the pump 10 is controlled by the control unit 13. However, the present disclosure is not limited thereto. For example, the pumping flow rate of the pump 10 may be controlled by an operator.

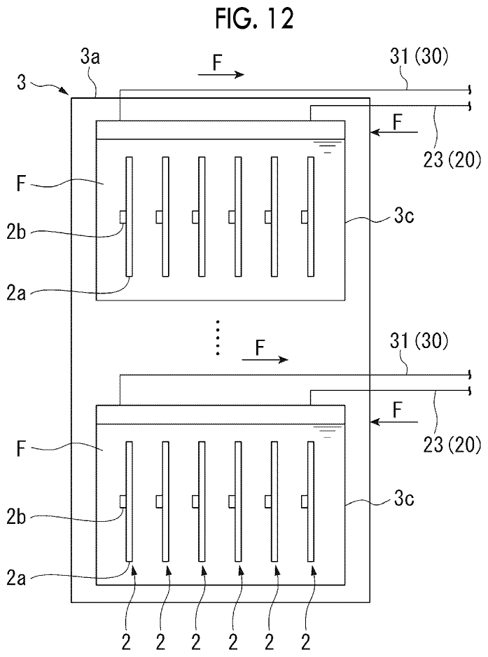

In the above-described embodiments, a case has been described in which each rack 3 includes a cold plate 3b for each chip 2b and each chip 2b is locally cooled. However, the present disclosure is not limited thereto. For example, as shown in FIG. 12, the rack 3 may include a cooling tank 3c that stores the refrigerant F to an extent that the plurality of servers 2 can be immersed. In this case, the supply line 20 and the discharge line 30 are connected to the cooling tank 3c.

### Additional Notes

The cooling system 1, 101, 201, 301, and 401 described in each embodiment is understood as follows, for example.

(1) The cooling system 1, 101, 201, 301, and 401 of a first aspect each includes a plurality of racks 3, each accommodating a heat generating body, a supply line 20 that supplies a refrigerant F for cooling the heat generating body to each of the racks 3, a discharge line 30 that discharges the refrigerant F that has passed through each of the racks 3, a turbine 8 into which the refrigerant F that has flowed through each discharge line 30 is introduced and which is rotationally driven by the refrigerant F, a cooling part 9 that cools the refrigerant F that has passed through the turbine 8 and that leads the refrigerant F to the supply line 20, and a pump 10 that is provided in each supply line 20, that is independently drivable, and that pumps the refrigerant F to the rack 3.

Examples of the heat generating body include the chip 2b of the above-described embodiments.

According to this aspect, the pumps 10 provided for each supply line 20 can be driven independently of each other. Therefore, the pump 10 can be controlled for each supply line 20. In this manner, the supply amount of the refrigerant F to each heat generating body can be controlled according to the amount of heat generated. In addition, the refrigerant F in an amount corresponding to the amount of heat generated by each heat generating body is supplied to each heat generating body in this way, and the refrigerant F can be efficiently heated. For this reason, in the vicinity of the outlet of the rack 3 in the circulation cycle of the refrigerant F in the cooling systems 1, 101, 201, 301, and 401, the refrigerant F can be sufficiently heated to the vicinity of the vaporization temperature and can be in a heated state. In this way, the turbine 8 can be stably rotationally driven by the refrigerant F sufficiently heated by each heat generating body.

(2) The cooling system 101, 201, 301, and 401 of a second aspect is the cooling system 101, 201, 301, 401 of the aspect (1), and may further include a branch line 14 that branches the refrigerant F that has flowed through the discharge line 30 on an upstream side of the turbine 8 and that guides a branched portion of the refrigerant F to a downstream side of the turbine 8.

In this manner, a portion of the refrigerant F can be released from the branch line 14, and the internal pressure in the turbine 8 can be reduced. In this manner, a load applied to the turbine 8 can be reduced.

(3) In the cooling system 401 of a third aspect, in the cooling system 401 of the aspect (2), a plurality of the branch lines 14 may be provided.

In this manner, the flow rate of the refrigerant F that can be released from the branch line 14 can be increased, and the pressure range that can be adjusted by the branch line 14 can be widened.

(4) The cooling system 301 or 401 of a fourth aspect is the cooling system 301 or 401 of the aspect (2) or (3), and may further include the second cooling part 16 that is provided in the branch line 14, that cools the refrigerant F, and that leads the refrigerant F to the supply line 20.

In this manner, the refrigerant F flowing through the branch line 14 can be cooled and condensed by the second cooler part. Therefore, since the pressure of the branch line 14 can be lowered, a decrease in the front-rear differential pressure of the turbine 8 can be suppressed, and the output of the turbine 8 can be kept constant.

(5) The cooling system 301 or 401 of a fifth aspect is the cooling system 301 or 401 of any one of the aspects (2) to (4), and may further include a second turbine 17 that is provided in the branch line 14 and that is rotationally driven by the refrigerant F.

In this manner, the second turbine 17 can be driven by the refrigerant F released by the branch line 14. Therefore, the heat of the heat generating body recovered by the refrigerant F can be utilized more efficiently. Further, for example, when the turbine 8 is not operated, the second turbine 17 can be operated, and redundancy can be provided. In addition, in a case where a plurality of the branch lines 14 are provided, a plurality of the second turbines 17 can be installed, and the redundancy can be further increased.

(6) The cooling system 1, 101, 201, 301, and 401 of a sixth aspect is the cooling system 1, 101, 201, 301, and 401 of any one of the aspects (1) to (5), and may further include a sensor 12 that detects an amount of heat generated for each rack 3, and a control unit 13 that controls a pumping flow rate of the pump 10 according to the amount of heat generated for each rack 3.

In this manner, the refrigerant F corresponding to the amount of heat generated by each heat generating body can be accurately supplied to each heat generating body. Therefore, the heat generated by each heat generating body can be more efficiently recovered by the refrigerant F.

(7) The cooling system 201, 301, and 401 of a seventh aspect is the cooling system 201, 301, and 401 of any one of the aspects (1) to (6), and may further include a buffer tank 15 that is disposed on an upstream side of the turbine 8 and that is capable of storing the refrigerant F that has flowed through the discharge line 30.

In this manner, the refrigerant F recovered from each rack 3 can be stored in the buffer tank 15 once, and the pressure can be made uniform and stabilized in the buffer tank 15. Thereafter, the refrigerant F can be supplied to the turbine 8.

(8) The cooling system 1, 101, 201, 301, and 401 of an eighth aspect is the cooling system 1, 101, 201, 301, and 401 of any one of the aspects (1) to (7), and may further include a heating part 40 that is provided in the discharge line 30 and that heats the refrigerant F.

In this manner, the temperature of the refrigerant F after passing through the rack 3 can be adjusted to a temperature sufficient to drive the turbine 8 by heating the refrigerant F with the heating part 40.

(9) The cooling system 1, 101, 201, 301, and 401 of a ninth aspect is the cooling system 1, 101, 201, 301, and 401 of any one of the aspects (1) to (8), in which the rack 3 may include a cold plate 3b provided for each of the heat generating bodies, the supply line 20 may supply the refrigerant F to each cold plate 3b, and the discharge line 30 may discharge the refrigerant F from each cold plate 3b.

Accordingly, since each heat generating body can be locally cooled, a plurality of heat generating bodies can be more efficiently cooled. In addition, the heat generated by each heat generating body can be efficiently recovered by the refrigerant F and can be used for rotational drive of the turbine 8.

### Industrial Applicability

According to the cooling system of the present disclosure, while the plurality of heat generating bodies are cooled, the heat generated by the plurality of heat generating bodies can be efficiently utilized.

### REFERENCE SIGNS LIST

1: cooling system
2: server
2a: server board
2b: chip
3: rack
3a: rack body
3b: cold plate
3c: cooling tank
4: receiver tank
5: distribution header
6: collecting header
7: intermediate line
8: turbine
8a: generator
9: cooling part
10: pump
11: valve
11a: gas release valve
11b: partition valve
12: sensor
13: control unit
13a: receiving part
13b: determination part
13c: control part
13d: second receiving part
13e: second determination part
13f: second control part
14: branch line
15: buffer tank
16: second cooling part
17: second turbine
20: supply line
21: first supply line
22: supply header
23: second supply line
30: discharge line
31: first discharge line
32: discharge header
33: second discharge line
40: heating part
41: heat storage material
50: second sensor
101: cooling system
201: cooling system
301: cooling system
401: cooling system
1100: computer
1110: processor
1120: main memory
1130: storage
1140: interface
F: refrigerant

1. A cooling system comprising:
a plurality of racks, each accommodating a heat generating body;
a supply line that supplies a refrigerant for cooling the heat generating body to each of the racks;
a discharge line that discharges the refrigerant that has passed through each of the racks;
a gas release valve provided on the downstream side of the discharge line;
a turbine into which the refrigerant that has flowed through each discharge line is introduced and which is rotationally driven by the refrigerant;
a cooling part that cools the refrigerant that has passed through the turbine and that leads the refrigerant to the supply line; and
a pump that is provided in each supply line, that is independently drivable, and that pumps the refrigerant to the racks.

2. The cooling system according to claim 1, further comprising:
a branch line that branches the refrigerant that has flowed through the discharge line on an upstream side of the turbine and that guides a branched portion of the refrigerant to a downstream side of the turbine.

3. The cooling system according to claim 2,
wherein a plurality of the branch lines are provided.

4. The cooling system according to claim 2, further comprising:
a second cooling part that is provided in the branch line, that cools the refrigerant, and that leads the refrigerant to the supply line.

5. The cooling system according to claim 2, further comprising:
a second turbine that is provided in the branch line and that is rotationally driven by the refrigerant.

6. The cooling system according to claim 1, further comprising:
a sensor that detects an amount of heat generated for each rack; and
a control unit that controls a pumping flow rate of the pump according to the amount of heat generated for each rack.

7. The cooling system according to claim 1, further comprising:
a buffer tank that is disposed on an upstream side of the turbine and that is capable of storing the refrigerant that has flowed through the discharge line.

8. The cooling system according to claim 1, further comprising:
a heating part that is provided in the discharge line and that heats the refrigerant.

9. The cooling system according to claim 1,
wherein the rack includes a cold plate provided for each of the heat generating bodies,
the supply line supplies the refrigerant to each cold plate, and
the discharge line discharges the refrigerant from each cold plate.
